(19) United States
(12) Patent Application Publication
(10) Pub. No.: US 2026/0106478 A1
(43) Pub. Date: Apr. 16, 2026

(54) PULSE CHARGING SYSTEM FOR A LITHIUM-ION BATTERY PACK

(71) Applicant: GM Global Technology Operations LLC, Detroit, MI (US)

(72) Inventors: Rasoul Salehi, Ann Arbor, MI (US); Brian J. Koch, Berkley, MI (US); Xinyu Du, Oakland Township, MI (US); Shengbing Jiang, Rochester Hills, MI (US); Shiming Duan, Ann Arbor, MI (US); Chaitanya Sankavaram, Rochester Hills, MI (US)

(21) Appl. No.: 18/911,434

(22) Filed: Oct. 10, 2024

(51) Int. Cl. H02J 7/00; B60L 53/62; B60L 53/66; G01R 31/389

(52) U.S. Cl. CPC H02J 7/927; B60L 53/62; B60L 53/665; G01R 31/389; H02J 7/82

(57) ABSTRACT

A pulse charging system for a lithium-ion battery pack includes one or more controllers in electronic communication with the lithium-ion battery pack. The one or more controllers include one or more processors that execute instructions to estimate a plating intensity of the lithium-ion battery pack during two or more initial pulse charging cycles of the lithium-ion battery pack. The one or more controllers calculate an updated plating intensity of the lithium-ion battery pack corresponding to a subsequent pulse charging cycle that is determined based on the plating intensity of the lithium-ion battery pack. In response to determining the updated plating intensity falls within an acceptable range of plating intensity values, the one or more controllers execute an optimized pulse charging cycle that is based on the updated plating intensity.

### INTRODUCTION

The present disclosure relates to a pulse charging system for a lithium-ion battery pack that determines a plurality of pulse charging parameters based on the plating intensity of the lithium-ion battery pack as the lithium-ion battery pack is pulse charged. The plurality of pulse charging parameters are selected to minimize the amount of lithium plating and maximize the charging rate of the lithium-ion battery pack.

Lithium-ion batteries are a type of rechargeable battery that are employed in a wide variety of applications such as, for example, electric vehicles, portable electronics such as smartphones and digital cameras, and grid storage applications. There are various battery charging management strategies currently available. One charging strategy that is commonly employed is pulse charging, which provides faster charging speeds and may also reduce instances of lithium plating when compared to some other types of charging approaches.

Lithium plating refers to the formation of dendrite material that is mainly formed from metallic lithium on the anode of a lithium-ion battery and often occurs under rapid charging conditions and lower temperatures. To reduce the instances of lithium plating, a lithium-ion battery may be pulse charged based on a frequency-designed pulsation and rest times between pulses. However, longer rest times between pulses increase the overall charging time. Another approach to reduce the effects of lithium plating involves detecting lithium plating during a charging event. There are various plating detection techniques that are mentioned in literature that are available, however, many of these plating detection techniques may not be practical to implement or are not capable of detecting lithium plating in some types of lithium-ion cells. For example, some types of plating detection techniques require relatively long rest periods after being charged to determine the lithium plating, instead of being detected during the charging cycle. Another alternative is to implement a model-based algorithm that includes non-linear lithium-ion battery models with online calibration that take battery cell aging characteristics into account when calculating pulse charging parameters. However, because of their complexity, these lithium-ion battery models may require significant computing resources and may not be easily implemented to detect lithium plating.

Thus, while current pulse charging techniques achieve their intended purpose, there is a need in the art for an improved approach for pulse charging lithium-ion batteries.

### SUMMARY

According to several aspects, a pulse charging system for a lithium-ion battery pack is disclosed. The pulse charging system includes one or more controllers in electronic communication with the lithium-ion battery pack. The one or more controllers include one or more processors that execute instructions to estimate a plating intensity of the lithium-ion battery pack during two or more initial pulse charging cycles of the lithium-ion battery pack. The one or more controllers estimate a plurality of pulse charging parameters for the two or more initial pulse charging cycles that include a change in a state-of-charge of the lithium-ion battery and a rest time by minimizing a cost function that produces an output based on the plating intensity. The one or more controllers determine an initial change in the state-of-charge of the lithium-ion battery and an initial rest time during the two or more initial pulse charging cycles by a model-free numerical optimization approach that is based on the cost function. The one or more controllers execute two successive pulse charging cycles that include a first pulse charging cycle and a second pulse charging cycle, where the first pulse charging cycle is based on the initial change in the state-of-charge of the lithium-ion battery and the initial rest time, and the second pulse charging cycle is based on a subsequent change in the state-of-charge of the lithium-ion battery and a subsequent rest time. The one or more controllers determine a second updated change in the state-of-charge of the lithium-ion battery and a second updated rest time corresponding to the two successive pulse charging cycles by the model-free numerical optimization approach. The one or more controllers execute a subsequent pulse charging cycle based on the second updated change in the state-of-charge of the lithium-ion battery and the second updated rest time. The one or more controllers calculate an updated plating intensity of the lithium-ion battery pack corresponding to the subsequent pulse charging cycle, and in response to determining the updated plating intensity falls within an acceptable range of plating intensity values, the one or more controllers execute an optimized pulse charging cycle that is based on the updated plating intensity.

In another aspect, estimating the plating intensity of the lithium-ion battery pack includes: determining a state-of-charge of the lithium-ion battery pack, and controlling power supplied to the lithium-ion battery pack to create the two or more initial pulse charging cycles, wherein the state-of-charge of the lithium-ion battery pack is greater than a pulse state-of-charge of the lithium-ion battery pack at which a current pulse is applied.

In yet another aspect, estimating the plating intensity of the lithium-ion battery pack includes: estimating a cell impedance of the lithium-ion battery pack for the two or more initial pulse charging cycles based on a change in cell voltage of the lithium-ion battery during a reduced-current mode of a pulse charging cycle and a change in cell current of the lithium-ion battery during a reduced-current mode of the pulse charging cycle.

In an aspect, estimating the plating intensity of the lithium-ion battery pack includes: forming a spline representing a relationship between a trigger voltage and the cell impedance of the lithium-ion battery pack for the two or more initial pulse charging cycles, and estimating the plating intensity of the lithium-ion battery pack based on a curvature of the spline.

In another aspect, trigger voltage represents the cell voltage of the lithium-ion battery pack at which a current pulse is applied.

In yet another aspect, the one or more controllers determine the curvature of the spline by:

$$k = {d}^{2} Ω / {dV}_{trigger}^{2} / [ {( 1 + {( \frac{d Ω}{{dV}_{trigger}} )}^{2} )}^{\frac{3}{2}} ) ]$$

where k represents the curvature of the spline, Ω represents the cell impedance of the lithium-ion battery pack, and V_{trigger} represents the trigger voltage.

In an aspect, the plating intensity is equal to the minimum value of the curvature of the spline.

In another aspect, the curvature of the spline is determined based on one or more machine learning algorithms.

In yet another aspect, the curvature of the spline is determined based on the forward Euler method.

In an aspect, the cost function is expressed as:

$${min}_{δ SOC , {T}_{rest}} J = {T}_{charge} - β {Q}_{pl}$$

where J represents the cost, δSOC represents the change in the state-of-charge of the lithium-ion battery pack, Tᵣₑₛₜ represents the rest time, β represents a weighting factor that is calibrated, Qₚₗ represents the plating intensity, and T_{charge} represents an overall charging time.

In another aspect, the model-free numerical optimization approach is one of the following: gradient descent, the Newton-Raphson method, and the Nelder-Mead method.

In yet another aspect, the initial change in the state-of-charge is unequal to the subsequent change in the state-of-charge of the lithium-ion battery by a difference of at least about 5 percent.

In an aspect, the initial rest time is unequal to the subsequent rest time by a difference of at least about 5 percent.

In another aspect, the acceptable range of plating intensity values include a minimum acceptable plating intensity that is about zero and a maximum plating intensity.

In yet another aspect, a pulse charging system for a lithium-ion battery pack. The pulse charging system includes one or more controllers in electronic communication with the lithium-ion battery pack, where the one or more controllers include one or more processors that execute instructions to estimate a plating intensity of the lithium-ion battery pack during two or more initial pulse charging cycles of the lithium-ion battery pack. Estimating the plating intensity of the lithium-ion battery pack includes determining a state-of-charge of the lithium-ion battery pack, and controlling power supplied to the lithium-ion battery pack to create the two or more initial pulse charging cycles, where the state-of-charge of the lithium-ion battery pack is greater than a pulse state-of-charge of the lithium-ion battery pack at which a current pulse is applied. The one or more controllers estimate a plurality of pulse charging parameters for the two or more initial pulse charging cycles that include a change in a state-of-charge of the lithium-ion battery and a rest time by minimizing a cost function that produces an output based on the plating intensity. The one or more controllers determine an initial change in the state-of-charge of the lithium-ion battery and an initial rest time during the two or more initial pulse charging cycles by a model-free numerical optimization approach that is based on the cost function. The one or more controllers execute two successive pulse charging cycles that include a first pulse charging cycle and a second pulse charging cycle, where the first pulse charging cycle is based on the initial change in the state-of-charge of the lithium-ion battery and the initial rest time, and the second pulse charging cycle is based on a subsequent change in the state-of-charge of the lithium-ion battery and a subsequent rest time. The one or more controllers determine a second updated change in the state-of-charge of the lithium-ion battery and a second updated rest time corresponding to the two successive pulse charging cycles by the model-free numerical optimization approach. The one or more controllers execute a subsequent pulse charging cycle based on the second updated change in the state-of-charge of the lithium-ion battery and the second updated rest time. The one or more controllers calculate an updated plating intensity of the lithium-ion battery pack corresponding to the subsequent pulse charging cycle, and in response to determining the updated plating intensity falls within an acceptable range of plating intensity values, execute an optimized pulse charging cycle that is based on the updated plating intensity.

In an aspect, estimating the plating intensity of the lithium-ion battery pack includes: estimating a cell impedance of the lithium-ion battery pack for the two or more initial pulse charging cycles based on a change in cell voltage of the lithium-ion battery during a reduced-current mode of a pulse charging cycle and a change in cell current of the lithium-ion battery during a reduced-current mode of the pulse charging cycle.

In another aspect, estimating the plating intensity of the lithium-ion battery pack includes: forming a spline representing a relationship between a trigger voltage and the cell impedance of the lithium-ion battery pack for the two or more initial pulse charging cycles, and estimating the plating intensity of the lithium-ion battery pack based on a curvature of the spline.

In yet another aspect, the one or more controllers determine the curvature of the spline by:

$$k = {d}^{2} Ω / {dV}_{trigger}^{2} / [ {( 1 + {( \frac{d Ω}{{dV}_{trigger}} )}^{2} )}^{\frac{3}{2}} ) ]$$

where k represents the curvature of the spline, Ω represents the cell impedance of the lithium-ion battery pack, and V_{trigger} represents the trigger voltage.

In an aspect, the cost function is expressed as:

$${min}_{δ SOC , {T}_{rest}} J = {T}_{charge} - β {Q}_{pl}$$

where J represents the cost, δSOC represents the change in the state-of-charge of the lithium-ion battery pack, Tᵣₑₛₜ represents the rest time, β represents a weighting factor that is calibrated, Qₚₗ represents the plating intensity, and T_{charge} represents an overall charging time.

In another aspect, a pulse charging system for a lithium-ion battery pack for an all-electric vehicle is disclosed. The pulse charging system includes one or more electric motors that are powered by the lithium-ion battery pack and one or more controllers in electronic communication with the lithium-ion battery pack and the one or more electric motors. The one or more controllers include one or more processors that execute instructions to estimate a plating intensity of the lithium-ion battery pack during two or more initial pulse charging cycles of the lithium-ion battery pack. Estimating the plating intensity of the lithium-ion battery pack includes determining a state-of-charge of the lithium-ion battery pack, controlling power supplied to the lithium-ion battery pack to create the two or more initial pulse charging cycles, where the state-of-charge of the lithium-ion battery pack is greater than a pulse state-of-charge of the lithium-ion battery pack at which a current pulse is applied, estimating a cell impedance of the lithium-ion battery pack for the two or more initial pulse charging cycles based on a change in cell voltage of the lithium-ion battery during a reduced-current mode of a pulse charging cycle and a change in cell current of the lithium-ion battery during a reduced-current mode of the pulse charging cycle, forming a spline representing a relationship between a trigger voltage and the cell impedance of the lithium-ion battery pack for the two or more initial pulse charging cycles, and estimating the plating intensity of the lithium-ion battery pack based on a curvature of the spline. The one or more controllers estimate a plurality of pulse charging parameters for the two or more initial pulse charging cycles that include a change in a state-of-charge of the lithium-ion battery and a rest time by minimizing a cost function that produces an output based on the plating intensity. The one or more controllers determine an initial change in the state-of-charge of the lithium-ion battery and an initial rest time during the two or more initial pulse charging cycles by a model-free numerical optimization approach that is based on the cost function. The one or more controllers execute two successive pulse charging cycles that include a first pulse charging cycle and a second pulse charging cycle, wherein the first pulse charging cycle is based on the initial change in the state-of-charge of the lithium-ion battery and the initial rest time, and the second pulse charging cycle is based on a subsequent change in the state-of-charge of the lithium-ion battery and a subsequent rest time. The one or more controllers determine a second updated change in the state-of-charge of the lithium-ion battery and a second updated rest time corresponding to the two successive pulse charging cycles by the model-free numerical optimization approach. The one or more controllers execute a subsequent pulse charging cycle based on the second updated change in the state-of-charge of the lithium-ion battery and the second updated rest time. The one or more controllers calculate an updated plating intensity of the lithium-ion battery pack corresponding to the subsequent pulse charging cycle, and in response to determining the updated plating intensity falls within an acceptable range of plating intensity values, execute an optimized pulse charging cycle that is based on the updated plating intensity.

Further areas of applicability will become apparent from the description provided herein. It should be understood that the description and specific examples are intended for purposes of illustration only and are not intended to limit the scope of the present disclosure.

### BRIEF DESCRIPTION OF THE DRAWINGS

The drawings described herein are for illustration purposes only and are not intended to limit the scope of the present disclosure in any way.

FIG. 1 is an exemplary schematic diagram of a vehicle including the disclosed pulse charging system for a lithium-ion battery pack, according to an exemplary embodiment;

FIG. 2A illustrates a graph representing an anode potential of the lithium-ion battery pack during a reduced-current mode of a pulse charging cycle, according to an exemplary embodiment;

FIG. 2B illustrates a graph representing a cathode potential of the lithium-ion battery pack during the reduced-current mode of a pulse charging cycle, according to an exemplary embodiment;

FIG. 2C illustrates a graph representing a change in cell current of the lithium-ion battery pack during the reduced-current mode of the pulse charging cycle, according to an exemplary embodiment;

FIG. 2D illustrates a graph representing a cell voltage of the lithium-ion battery pack, according to an exemplary embodiment;

FIG. 3 is a graph illustrating a plurality of exemplary splines that each represent a relationship between a trigger voltage and a cell impedance of the lithium-ion battery pack for two or more pulse charging cycles, according to an exemplary embodiment;

FIG. 4 is a process flow diagram illustrating a method for estimating the plating intensity of the lithium-ion battery pack, according to an exemplary embodiment; and

FIG. 5 is a process flow diagram illustrating a method for calculating an updated plating intensity and determining if the updated plating intensity falls within an acceptable range of plating intensity values, according to an exemplary embodiment.

### DETAILED DESCRIPTION

The following description is merely exemplary in nature and is not intended to limit the present disclosure, application, or uses.

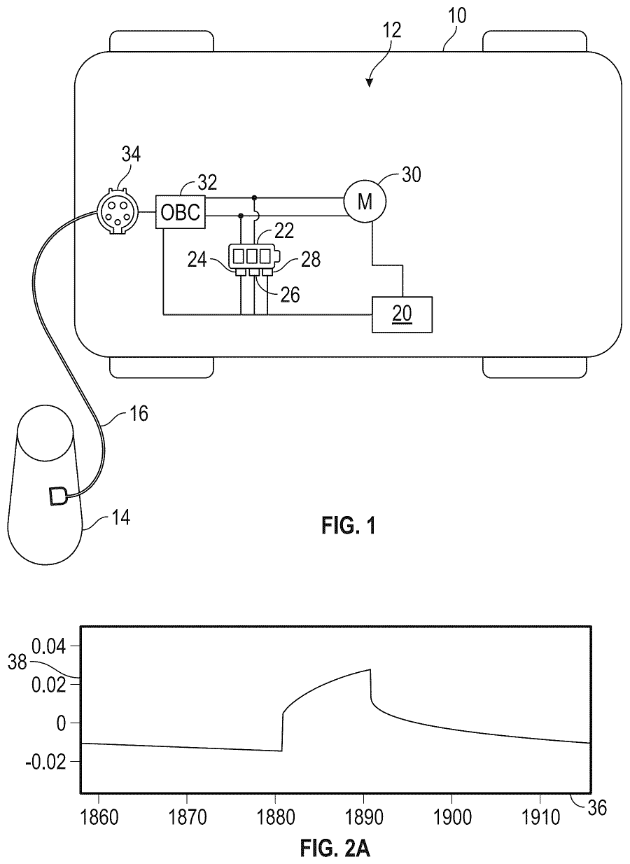

Referring to FIG. 1, an exemplary schematic diagram of a vehicle 10 including the disclosed pulse charging system 12 is illustrated. The pulse charging system 12 includes one or more controllers 20 in electronic communication with a lithium-ion battery pack 22, one or more voltage sensors 24, one or more current sensors 26, one or more temperature sensors 28, one or more electric motors 30, and an on-board charger 32. In the embodiment as shown in FIG. 1, the vehicle 10 is an all-electric vehicle that receives all the motive power from the one or more electric motors 30 that are powered by the lithium-ion battery pack 22. The one or more voltage sensors 24 monitor a voltage of the lithium-ion battery pack 22 in real-time, the one or more current sensors 26 monitor a discharge current of the lithium-ion battery pack 22 in real-time, and the one or more temperature sensors 28 monitor a battery temperature of the lithium-ion battery pack 22 in real-time.

In the embodiment as shown in FIG. 1, the on-board charger 32 is electrically connected to an electric vehicle charging station 14. The electric vehicle charging station 14 supplies the electrical power to charge the lithium-ion battery pack 22. The electric vehicle charging station 14 may include a charging cable 16 that electrically couples to a receiving connector 34 of the vehicle 10. The receiving connector 34 of the vehicle 10 is electrically connected to the on-board charger 32. The on-board charger 32 converts alternating current (AC) power supplied from the electric vehicle charging station 14 into direct current (DC) power that is supplied the lithium-ion battery pack 22. In the event the electric vehicle charging station 14 provides DC power, then the on-board charger 32 may be bypassed and the DC power may be provided to the lithium-ion battery pack 22.

It is to be appreciated that the vehicle 10 may be any type of vehicle such as, but not limited to, a sedan, a truck, sport utility vehicle, van, or motor home. It is also to be appreciated that while FIG. 1 illustrates an electric vehicle, the pulse charging system 12 is not limited to an electric vehicle and may be used in any other application that includes a lithium-ion battery pack. Some examples of other applications that may include the pulse charging system 12 include, but are not limited to, portable electronics such as smartphone and tablet computers, drones, and aerial vehicles.

As explained below, the one or more controllers 20 of the pulse charging system 12 estimate a plating intensity Qₚₗ of the lithium-ion battery pack 22 for two or more pulse charging cycles of the lithium-ion battery pack 22, where each pulse charging cycle includes an increased-current mode where a current pulse is applied to the lithium-ion battery pack 22 and a reduced-current mode that represents a pause between current pulses. The one or more controllers 20 calculate a plurality of pulse charging parameters based on the plating intensity Qₚₗ of the lithium-ion battery pack 22. In one embodiment, the plurality of pulse charging parameters include a change in the state-of-charge δSOC of the lithium-ion battery pack 22 during the increased-current mode of the pulse charging cycles and a rest time Tᵣₑₛₜ that represents a duration of time of the reduced-current mode of the pulse charging cycles lasts. In one non-limiting embodiment, the plurality of pulse charging parameters may also include a charging rate of the lithium-ion battery pack 22.

It is to be appreciated that the plurality of pulse charging parameters are selected to minimize the amount of lithium plating within the lithium-ion battery pack 22 while at the same time maximizing the charging rate of the lithium-ion battery pack 22. In other words, the plurality of pulse charging parameters are optimized to result in a minimum amount of lithium plating within the lithium-ion battery pack 22 and a maximized charging rate to reduce the total amount of time required to charge the lithium-ion battery pack 22. It is also to be appreciated that while the disclosure describes a plurality of pulse charging parameters to minimize lithium plating, a similar approach may be used to limit or minimize other types of side reactions as well such as, for example, solid electrolyte interface (SEI) growth.

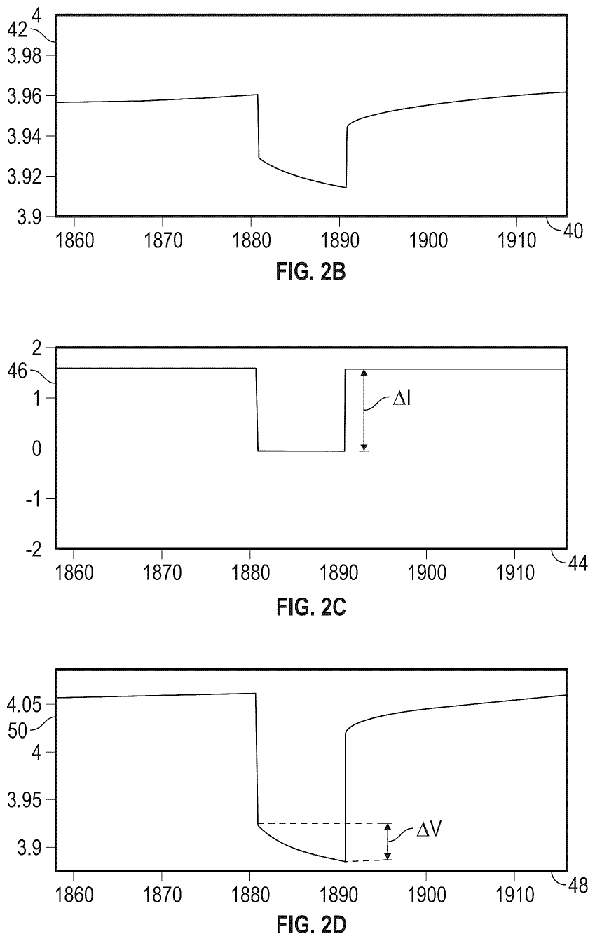

FIG. 2A illustrates a graph including an x-axis 36 representing time (in seconds) and a y-axis 38 representing an anode potential U_{anode} of the lithium-ion battery pack 22 during the reduced-current mode of a pulse charging cycle. FIG. 2B illustrates a graph including an x-axis 40 representing time and a y-axis 42 representing a cathode potential U_{cathode} of the lithium-ion battery pack 22 during the reduced-current mode of a pulse charging cycle. FIG. 2C illustrates a graph including an x-axis 44 representing time and a y-axis 46 representing the cell current of the lithium-ion battery pack 22, where a change in cell current ΔI of the lithium-ion battery pack 22 during the reduced-current mode of the pulse charging cycle is shown. FIG. 2D illustrates a graph including an x-axis 48 representing time and a y-axis 50 representing cell voltage of the lithium-ion battery pack 22, where a voltage droop or change in cell voltage ΔV of the lithium-ion battery pack 22 during the reduced-current mode of the pulse charging cycle is shown.

Referring to FIGS. 2A-2D, it is to be appreciated that the change in cell voltage ΔV of the lithium-ion battery pack 22 decreases during the reduced-current mode of the pulse charging cycle because of various mechanisms that are triggered after a lithium plating mechanism such as, for example, lithium stripping. Lithium stripping refers to fragmentation of plated lithium from deposited plated lithium on the anode electrodes of the lithium-ion battery pack 22. It is to be appreciated that the change in cell voltage ΔV of the lithium-ion battery pack 22 is first measured, and the cell impedance Ω of the lithium-ion battery pack 22 is then estimated. The cell impedance Ω is estimated as the cell voltage ΔV divided by the cell current ΔI of the lithium-ion battery pack 22 during the reduced-current mode of the pulse charging cycle, or

$$Ω = \frac{Δ V}{Δ I} .$$

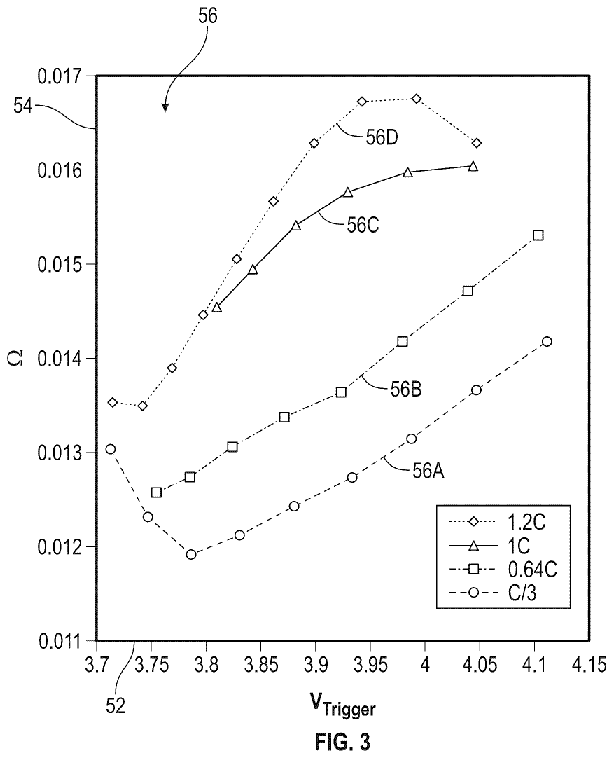

FIG. 3 is a graph illustrating a plurality of exemplary splines 56 that each represent a relationship between a trigger voltage V_{trigger} and the cell impedance Ω of the lithium-ion battery pack 22 for four pulse charging cycles. The trigger voltage V_{trigger} represents the cell voltage of the lithium-ion battery pack 22 at which a current pulse is applied. Specifically, the graph includes an x-axis 52 that represents the trigger voltage V_{trigger} and a y-axis 54 that represents the cell impedance 12 of the lithium-ion battery pack 22. Each spline 56 corresponds to a specific rate of time in which it takes to charge the lithium-ion battery pack 22 or the c-rate, where the spline 56A represents two or more pulse charging cycles at a c-rate of C/3, the spline 56B represents two or more pulse charging cycles at a c-rate of 0.64C, the spline 56C represents two or more pulse charging cycles at a c-rate of 1C, and the spline 56D represents two or more pulse charging cycles at a c-rate of 1.2C, where C represents cell capacity. It is appreciated that while FIG. 3 illustrates a plurality of splines 56, the relationship representing the relationship between the trigger voltage V_{trigger} and the cell impedance Ω of the lithium-ion battery pack 22 may be represented by any other continuous function such as, for example, a polynomial as well.

It is to be appreciated that as the c-rate increases, so does the plating intensity Qₚₗ of the lithium-ion battery pack 22. It is also to be appreciated that as a curvature of the spline 56A, 56B, 56C, 56D increases in the negative direction, so does the plating intensity Qₚₗ of the lithium-ion battery pack 22. For example, the spline 56A representing the c-rate of C/3 results in a normalized curvature of about 0, while the spline 56D representing the c-rate of 1.2C results in a normalized curvature of about −0.15.

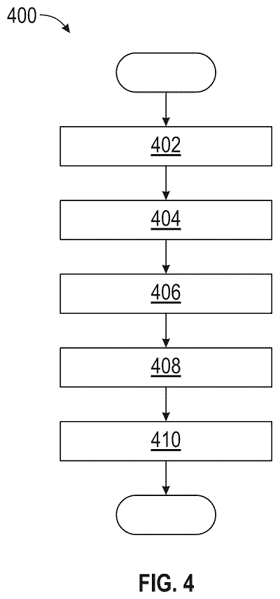

An approach to estimate the plating intensity Qₚₗ of the lithium-ion battery pack 22 shall now be described. It is to be appreciated that in the event the plating intensity Qₚₗ of the lithium-ion battery pack 22 is equal to zero, then random perturbations may be applied in a direction that increases the pulse charging rate. FIG. 4 is a process flow diagram illustrating a method 400 for estimating the plating intensity Qₚₗ of the lithium-ion battery pack 22 during two or more initial pulse charging cycles of the lithium-ion battery pack 22. Referring to FIGS. 1 and 4, the method 400 may begin at block 402. In block 402, the one or more controllers 20 determine the state-of-charge of the lithium-ion battery pack 22. The method 400 may then proceed to block 404.

In block 404, the one or more controllers 20 control the power supplied from the electric vehicle charging station 14 to the lithium-ion battery pack 22 to create the two or more initial pulse charging cycles. As mentioned above, each pulse charging cycle includes an increased-current mode where a current pulse is applied to the lithium-ion battery pack 22 and a reduced-current mode that represents a pause between the current pulses applied in the increased-current mode. The state-of-charge of the lithium-ion battery pack 22 is greater than a pulse state-of-charge of the lithium-ion battery pack 22 at which the current pulse is applied, or SOC>SOCₚᵤₗₛₑ, where SOCₚᵤₗₛₑ represents the pulse state-of-charge at which the current pulses are applied and SOC represents the state-of-charge of the lithium-ion battery pack 22. The method 400 may then proceed to block 406.

In block 406, the one or more controllers 20 estimate the cell impedance Ω of the lithium-ion battery pack 22 for the two or more initial pulse charging cycles based on the change in cell voltage ΔV of the lithium-ion battery pack 22 during the reduced-current mode of an individual pulse charging cycle and the change in cell current ΔI of the lithium-ion battery pack 22 during the reduced-current mode of the initial pulse charging cycle. Specifically, as mentioned above, the cell impedance Ω is the change in cell voltage ΔV divided by the cell current ΔI of the lithium-ion battery pack 22 during the reduced-current mode of the initial pulse charging cycle, or

$$Ω = \frac{Δ V}{Δ I} .$$

The method 400 may then proceed to block 408.

In block 408, the one or more controllers 20 form a spline 56 (seen in FIG. 3) representing a relationship between the trigger voltage V_{trigger} and the cell impedance Ω of the lithium-ion battery pack 22 for the two or more initial pulse charging cycles. The method 400 may then proceed to block 410.

In block 410, the one or more controllers 20 estimate the plating intensity Qₚₗ of the lithium-ion battery pack 22 based on the curvature of the spline 56 (FIG. 3) determined in block 408. Several approaches to determine the curvature of the spline 56 are described below. The method 400 may then terminate.

Referring to FIGS. 1 and 3, in one embodiment, the curvature of the spline 56 is determined by first calculating a curvature of the spline based on Equation 1, which is:

$$k = {d}^{2} Ω / {dV}_{trigger}^{2} / [ {( 1 + {( \frac{d Ω}{{dV}_{trigger}} )}^{2} )}^{\frac{3}{2}} ) ] \qquad Equation 1$$

where k represents the curvature of the spline 56. Once the curvature of the spline 56 is known, the one or more controllers 20 then solve for a continuous function ƒ(k) that correlates the curvature of the spline 56 to the plating intensity Qₚₗ. Specifically, the plating intensity Qₚₗ is equal to the minimum value of the curvature of the spline 56, which is expressed in Equation 2 as:

$$f ( k ) = \vert min ( [ {k}_{1} , {k}_{2} , ... ] , 0 \vert \qquad Equation 2$$

where kᵢ is the curvature at sample point i.

It is to be appreciated that other approaches to determine the curvature of the spline 56 may be used as well. For example, in another embodiment, the curvature of the spline 56 may be estimated based on one or more numerical approaches such as, for example, the forward Euler method. Specifically, the forward Euler method may be used to solve for the first and second order derivatives in Equation 1 to determine the curvature of the spline 56. In another embodiment, the curvature of the spline 56 may be determined based on one or more machine learning algorithms such as, but not limited to, a convolutional neural network (CNN) or a long short-term memory (LSTM) neural network.

Referring to FIG. 1, once the plating intensity Qₚₗ is determined, the one or more controllers 20 of the pulse charging system 12 estimate the plurality of pulse charging parameters for the two or more initial pulse charging cycles by minimizing a cost function that produces an output based on the plating intensity Qₚₗ and a time to charge T_{charge}, where the time to charge T_{charge} represents an overall charging time. Specifically, the plurality of pulse charging parameters include the change in the state-of-charge δSOC of the lithium-ion battery pack 22 during the increased-current mode of the initial pulse charging cycles and the rest time Tᵣₑₛₜ. In one embodiment, the cost function is expressed in Equations 3-7 as:

$${min}_{δ SOC , {T}_{rest}} J = {T}_{charge} - β {Q}_{pl} \qquad Equation 3$$

$$such that :$$

$${T}_{charge} = {α}_{1} {T}_{rest} + {α}_{2} ( 100 - δ SOC ) \qquad Equation 4$$

$$δ {SOC}_{max} > δ SOC > 0 \qquad Equation 5$$

$${Q}_{pl} \geq {Q}_{pl - min} \qquad Equation 6$$

$${T}_{rest} \geq 0 \qquad Equation 7$$

where J represents the cost that is used to find the values corresponding to the change in the state-of-charge δSOC of the lithium-ion battery pack 22 during the increased-current mode of the initial pulse charging cycles and the rest time Tᵣₑₛₜ, β represents a weighting factor that is calibrated, α₁ represents a first tuning parameter, α₂ represents a second tuning parameter, δSOCₘₐₓ represents a maximum allowable change in the state-of-charge δSOC of the lithium-ion battery pack 22 during the increased-current mode of the initial pulse charging cycles, and Qₚₗ₋ₘᵢₙ represents a minimum allowable plating intensity of the lithium-ion battery pack 22.

The one or more controllers 20 then determine a first updated change in the state-of-charge δSOC_{new} of the lithium-ion battery pack 22 during the increased-current mode of the two or more initial pulse charging cycles, a first updated rest time T_{rest,new} of the reduced-current mode of the two or more initial pulse charging cycles, an initial change in the state-of-charge δSOC₀ of the lithium-ion battery pack 22 during the increased-current mode of a first successive pulse charging cycle, and an initial rest time T_{rest,0} of the reduced-current mode of the first successive pulse charging cycle. The first updated change in the state-of-charge δSOC_{new} of the lithium-ion battery pack 22 and the first updated rest time T_{rest,new} represent the plurality of charging parameters determined based on the plating intensity Qₚₗ that was determined in method 400 shown in FIG. 4.

The first updated change in the state-of-charge δSOC_{new} of the lithium-ion battery pack 22, the first updated rest time T_{rest,new}, the initial change in the state-of-charge δSOC₀ of the lithium-ion battery pack 22, and the initial rest time T_{rest,0} are determined by a model-free numerical optimization approach that is based on the cost function that produces the output based on the plating intensity as described in Equation 3. Some examples of the model-free numerical optimization approach include, but are not limited to, the gradient descent, the Newton-Raphson method, or the Nelder-Mead method. In the example as described below, the gradient descent approach is employed to determine the first updated change in the state-of-charge δSOC_{new} of the lithium-ion battery pack 22, the first updated rest time T_{rest,new}, the initial change in the state-of-charge δSOC₀ of the lithium-ion battery pack 22, and the initial rest time T_{rest,0}, and is expressed in Equations 8-14 as:

$$δ {SOC}_{new} = δ {SOC}_{0} - {β}_{SOC} * ∇ {J}_{δ SOC} \qquad Equation 8$$

$${T}_{rest , new} = {T}_{rest , 0} - {β}_{T} * ∇ {J}_{Trest} \qquad Equation 9$$

$$∇ {J}_{δ SOC} = - {α}_{2} - \frac{β \partial {Q}_{pl}}{\partial δ SOC} \qquad Equation 10$$

$$∇ {J}_{Trest} = {α}_{1} - \frac{β \partial {Q}_{pl}}{\partial Trest} \qquad Equation 11$$

Assuming that a gradient of the plating intensity Qₚₗ with respect to the rest time Tᵣₑₛₜ is linearly related to a gradient of the plating intensity Qₚₗ with respect to the state-of-charge δSOC, which is expressed in Equation 12 as:

$$\partial {I}_{pl} / \partial {T}_{rest} = Γ \partial {Q}_{pl} / \partial δ SOC \approx ∇ {Q}_{pl} \qquad Equation 12$$

$$then$$

$$δ {SOC}_{new} = δ {SOC}_{0} - {β}_{SOC} ( - {α}_{2} - β ∇ {Q}_{pl} / Γ ) \qquad Equation 13$$

$${T}_{rest , new} = {T}_{rest , 0} - {β}_{T} ( {α}_{1} - β ∇ {Q}_{pl} ) \qquad Equation 14$$

where ∇J_{δSOC} represents a gradient of the cost function with respect to the change in the state-of-charge δSOC of the lithium-ion battery pack 22, ∇J_{Trest} represents a gradient of the cost function with respect to the rest time Tᵣₑₛₜ, Γ represents a linear correlation factor, β_{SOC} is a tuning parameter for the gradient method used to calculate δSOC_{new}, and β_{T} is a tuning parameter based on the rest time Tᵣₑₛₜ.

Once the first updated change in the state-of-charge δSOC_{new} of the lithium-ion battery pack 22, the first updated rest time T_{rest,new}, the initial change in the state-of-charge δSOC₀ of the lithium-ion battery pack 22, and the initial rest time T_{rest,0} are determined, the one or more controllers 20 execute two successive pulse charging cycles. Specifically, the two successive pulse charging cycles include a first pulse charging cycle and a second pulse charging cycle. The first pulse charging cycle is based on the initial change in the state-of-charge δSOC₀ of the lithium-ion battery pack 22 and the initial rest time T_{rest,0}, and the second pulse charging cycle is based on a subsequent change in the state-of-charge δSOC₁ of the lithium-ion battery pack 22 and a subsequent rest time T_{rest,1}. The initial change in the state-of-charge δSOC₀ is unequal to the subsequent change in the state-of-charge δSOC₁ of the lithium-ion battery pack 22 by a difference of at least about 5 percent. Similarly, the initial rest time T_{rest,0} is unequal to the subsequent rest time T_{rest,1} by a difference of at least about 5 percent.

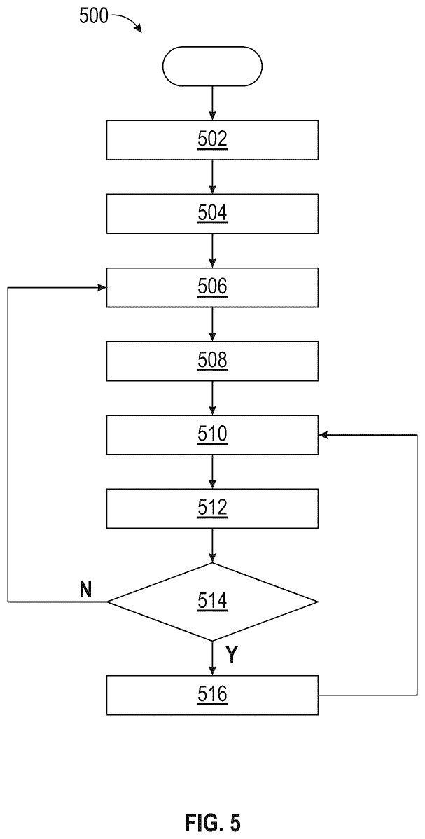

FIG. 5 is a process flow diagram illustrating a method 500 for calculating an updated plating intensity Q_{pl_new} and determining if the updated plating intensity Q_{pl_new} falls within an acceptable range of plating intensity values. In response to determining the updated plating intensity Q_{pl_new} falls within an acceptable range of plating intensity values, the one or more controllers 20 may then execute an optimized pulse charging cycle that is based on the updated plating intensity Q_{pl_new}. Referring to FIGS. 1 and 5, the method 500 may begin at block 502. In block 502, the one or more controllers 20 execute the two successive pulse charging cycles. The method 500 may then proceed to block 504.

In block 504, the one or more controllers 20 calculate an first plating intensity Q_{pl_0} that corresponds to the first pulse charging cycle of the two successive pulse charging cycles and a second plating intensity Q_{pl_1} that corresponds to the second pulse charging cycle of the two successive pulse charging cycles, where the method for determining the plating intensity is described above and illustrated as method 400 in FIG. 4. The method 500 may then proceed to block 506.

In block 506, the one or more controllers 20 calculate the gradient of the plating intensity ∇Qₚₗ for the two successive pulse charging cycles based on a change in plating intensity ∂Qₚₗ for the two successive pulse charging cycles and a change in the rest time ∂Tᵣₑₛₜ for the two successive pulse charging cycles. The change in plating intensity ∂Qₚₗ is the difference between the first plating intensity Q_{pl_1} and the second plating intensity Q_{pl_0} and the change in the rest time ∂Tᵣₑₛₜ is the difference between the first rest time Tᵣₑₛₜ₁ and the second rest Tᵣₑₛₜ₀. The gradient of the plating intensity ∇Qₚₗ is the change in plating intensity ∂Qₚₗ divided by the change in the rest time

$$\partial {T}_{rest} , or \frac{\partial {Q}_{pl}}{\partial {T}_{rest}} .$$

The method 500 may then proceed to block 508.

In block 508, the one or more controllers 20 determine a second updated change in the state-of-charge δSOC_{new} of the lithium-ion battery pack 22 during the increased-current mode of the two or more successive pulse charging cycles, a second updated rest time T_{rest,new} of the reduced-current mode of the two successive pulse charging cycles, a second initial change in the state-of-charge δSOC₀ of the lithium-ion battery pack 22 during the increased-current mode of a subsequent pulse charging cycle, and a second initial rest time T_{rest,0} of the reduced-current mode of a subsequent pulse charging cycle based on the gradient of the plating intensity ∇Qₚₗ calculated in block 506 and Equations 3-14 as described above. The method 500 may then proceed to block 510.

In block 510, the one or more controllers 20 then execute a subsequent pulse charging cycle based on the second updated change in the state-of-charge δSOC_{new} of the lithium-ion battery pack 22 and the second updated rest time T_{rest,new} determined in block 508. The method 500 may then proceed to block 512.

In block 512, the one or more controllers 20 determine the updated plating intensity Q_{pl_new} corresponding to the subsequent pulse charging cycle based on the method 400 shown in FIG. 4. The one or more controllers 20 may then set the initial plating intensity Q_{pl_0} equal to the subsequent plating intensity Q_{pl_1} and the subsequent plating intensity Q_{pl_1} equal to the updated plating intensity Q_{pl_new}. The method 500 may then proceed to decision block 514.

In decision block 514, the one or more controllers 20 compare the updated plating intensity Q_{pl_new} with the acceptable range of plating intensity values. The acceptable range of plating intensity values include a minimum acceptable plating intensity Q_{pl_min} that is equal to about zero and a maximum plating intensity Q_{pl_max} that is determined by the manufacturer of the lithium-ion battery pack 22 or the vehicle manufacturer. In response to determining the updated plating intensity Q_{pl_new} does not fall within the acceptable range of plating intensity values, the method 500 returns to block 506. In response to determining the updated plating intensity Q_{pl_new} falls within the acceptable range of plating intensity values, the method 500 may then proceed to block 516.

In block 516, the one or more controllers 20 executes one or more optimized pulse charging cycles. The one or more optimized pulse charging cycles include a plurality of optimized pulse charging parameters that are determined based on the on the updated plating intensity Q_{pl_new}. The one or more optimized pulse charging parameters result in minimizing the amount of lithium plating within the lithium-ion battery pack 22 while at the same time maximizing the charging rate of the lithium-ion battery pack 22. The method 500 may then return to block 510.

Referring generally to the figures, the disclosed pulse charging system provides various technical effects and benefits. Specifically, the pulse charging system provides a numerical approach to estimate the plating intensity of the lithium-ion battery pack based on the change in cell voltage as the lithium-ion battery pack is being pulse charged. The plating intensity of the lithium-ion battery pack is used to determine a plurality of pulse charging parameters that are optimized to result in a minimum amount of lithium plating within the lithium-ion battery cell and a maximized charging rate to reduce the total amount of time required to charge the lithium-ion battery cell.

The controllers may refer to, or be part of an electronic circuit, a combinational logic circuit, a field programmable gate array (FPGA), a processor (shared, dedicated, or group) that executes code, or a combination of some or all of the above, such as in a system-on-chip. Additionally, the controllers may be microprocessor-based such as a computer having a at least one processor, memory (RAM and/or ROM), and associated input and output buses. The processor may operate under the control of an operating system that resides in memory. The operating system may manage computer resources so that computer program code embodied as one or more computer software applications, such as an application residing in memory, may have instructions executed by the processor. In an alternative embodiment, the processor may execute the application directly, in which case the operating system may be omitted.

The description of the present disclosure is merely exemplary in nature and variations that do not depart from the gist of the present disclosure are intended to be within the scope of the present disclosure. Such variations are not to be regarded as a departure from the spirit and scope of the present disclosure.

What is claimed is:

1. A pulse charging system for a lithium-ion battery pack, the pulse charging system comprising:
one or more controllers in electronic communication with the lithium-ion battery pack, wherein the one or more controllers include one or more processors that execute instructions to:
estimate a plating intensity of the lithium-ion battery pack during two or more initial pulse charging cycles of the lithium-ion battery pack;
estimate a plurality of pulse charging parameters for the two or more initial pulse charging cycles that include a change in a state-of-charge of the lithium-ion battery and a rest time by minimizing a cost function that produces an output based on the plating intensity;
determine an initial change in the state-of-charge of the lithium-ion battery and an initial rest time during the two or more initial pulse charging cycles by a model-free numerical optimization approach that is based on the cost function;
execute two successive pulse charging cycles that include a first pulse charging cycle and a second pulse charging cycle, wherein the first pulse charging cycle is based on the initial change in the state-of-charge of the lithium-ion battery and the initial rest time, and the second pulse charging cycle is based on a subsequent change in the state-of-charge of the lithium-ion battery and a subsequent rest time;
determine a second updated change in the state-of-charge of the lithium-ion battery and a second updated rest time corresponding to the two successive pulse charging cycles by the model-free numerical optimization approach;
execute a subsequent pulse charging cycle based on the second updated change in the state-of-charge of the lithium-ion battery and the second updated rest time;
calculate an updated plating intensity of the lithium-ion battery pack corresponding to the subsequent pulse charging cycle; and
in response to determining the updated plating intensity falls within an acceptable range of plating intensity values, execute an optimized pulse charging cycle that is based on the updated plating intensity.

2. The pulse charging system of claim 1, wherein estimating the plating intensity of the lithium-ion battery pack includes:
determining a state-of-charge of the lithium-ion battery pack; and
controlling power supplied to the lithium-ion battery pack to create the two or more initial pulse charging cycles, wherein the state-of-charge of the lithium-ion battery pack is greater than a pulse state-of-charge of the lithium-ion battery pack at which a current pulse is applied.

3. The pulse charging system of claim 2, wherein estimating the plating intensity of the lithium-ion battery pack includes:
estimating a cell impedance of the lithium-ion battery pack for the two or more initial pulse charging cycles based on a change in cell voltage of the lithium-ion battery during a reduced-current mode of a pulse charging cycle and a change in cell current of the lithium-ion battery during a reduced-current mode of the pulse charging cycle.

4. The pulse charging system of claim 3, wherein estimating the plating intensity of the lithium-ion battery pack includes:
forming a spline representing a relationship between a trigger voltage and the cell impedance of the lithium-ion battery pack for the two or more initial pulse charging cycles; and
estimating the plating intensity of the lithium-ion battery pack based on a curvature of the spline.

5. The pulse charging system of claim 4, wherein trigger voltage represents the cell voltage of the lithium-ion battery pack at which a current pulse is applied.

6. The pulse charging system of claim 4, wherein the one or more controllers determine the curvature of the spline by:
$$k = {d}^{2} Ω / {dV}_{trigger}^{2} / [ {( 1 + {( \frac{d Ω}{{dV}_{trigger}} )}^{2} )}^{\frac{3}{2}} ) ]$$
wherein k represents the curvature of the spline, Ω represents the cell impedance of the lithium-ion battery pack, and V_{trigger} represents the trigger voltage.

7. The pulse charging system of claim 6, wherein the plating intensity is equal to the minimum value of the curvature of the spline.

8. The pulse charging system of claim 4, wherein the curvature of the spline is determined based on one or more machine learning algorithms.

9. The pulse charging system of claim 4, wherein the curvature of the spline is determined based on the forward Euler method.

10. The pulse charging system of claim 1, wherein the cost function is expressed as:
$${min}_{δ SOC , {T}_{rest}} J = {T}_{charge} - β {Q}_{pl}$$
wherein J represents the cost, δSOC represents the change in the state-of-charge of the lithium-ion battery pack, Tᵣₑₛₜ represents the rest time, β represents a weighting factor that is calibrated, Qₚₗ represents the plating intensity, and T_{charge} represents an overall charging time.

11. The pulse charging system of claim 1, wherein the model-free numerical optimization approach is one of the following: gradient descent, the Newton-Raphson method, and the Nelder-Mead method.

12. The pulse charging system of claim 1, wherein the initial change in the state-of-charge is unequal to the subsequent change in the state-of-charge of the lithium-ion battery by a difference of at least about 5 percent.

13. The pulse charging system of claim 1, wherein the initial rest time is unequal to the subsequent rest time by a difference of at least about 5 percent.

14. The pulse charging system of claim 1, wherein the acceptable range of plating intensity values include a minimum acceptable plating intensity that is about zero and a maximum plating intensity.

15. A pulse charging system for a lithium-ion battery pack, the pulse charging system comprising:
one or more controllers in electronic communication with the lithium-ion battery pack, wherein the one or more controllers include one or more processors that execute instructions to:
estimate a plating intensity of the lithium-ion battery pack during two or more initial pulse charging cycles of the lithium-ion battery pack, wherein estimating the plating intensity of the lithium-ion battery pack includes:
determining a state-of-charge of the lithium-ion battery pack; and
controlling power supplied to the lithium-ion battery pack to create the two or more initial pulse charging cycles, wherein the state-of-charge of the lithium-ion battery pack is greater than a pulse state-of-charge of the lithium-ion battery pack at which a current pulse is applied;
estimate a plurality of pulse charging parameters for the two or more initial pulse charging cycles that include a change in a state-of-charge of the lithium-ion battery and a rest time by minimizing a cost function that produces an output based on the plating intensity;
determine an initial change in the state-of-charge of the lithium-ion battery and an initial rest time during the two or more initial pulse charging cycles by a model-free numerical optimization approach that is based on the cost function;
execute two successive pulse charging cycles that include a first pulse charging cycle and a second pulse charging cycle, wherein the first pulse charging cycle is based on the initial change in the state-of-charge of the lithium-ion battery and the initial rest time, and the second pulse charging cycle is based on a subsequent change in the state-of-charge of the lithium-ion battery and a subsequent rest time;
determine a second updated change in the state-of-charge of the lithium-ion battery and a second updated rest time corresponding to the two successive pulse charging cycles by the model-free numerical optimization approach;
execute a subsequent pulse charging cycle based on the second updated change in the state-of-charge of the lithium-ion battery and the second updated rest time;
calculate an updated plating intensity of the lithium-ion battery pack corresponding to the subsequent pulse charging cycle; and
in response to determining the updated plating intensity falls within an acceptable range of plating intensity values, execute an optimized pulse charging cycle that is based on the updated plating intensity.

16. The pulse charging system of claim 15, wherein estimating the plating intensity of the lithium-ion battery pack includes:
estimating a cell impedance of the lithium-ion battery pack for the two or more initial pulse charging cycles based on a change in cell voltage of the lithium-ion battery during a reduced-current mode of a pulse charging cycle and a change in cell current of the lithium-ion battery during a reduced-current mode of the pulse charging cycle.

17. The pulse charging system of claim 16, wherein estimating the plating intensity of the lithium-ion battery pack includes:
forming a spline representing a relationship between a trigger voltage and the cell impedance of the lithium-ion battery pack for the two or more initial pulse charging cycles; and
estimating the plating intensity of the lithium-ion battery pack based on a curvature of the spline.

18. The pulse charging system of claim 17, wherein the one or more controllers determine the curvature of the spline by:
$$k = {d}^{2} Ω / {dV}_{trigger}^{2} / [ {( 1 + {( \frac{d Ω}{{dV}_{trigger}} )}^{2} )}^{\frac{3}{2}} ) ]$$
wherein k represents the curvature of the spline, Ω represents the cell impedance of the lithium-ion battery pack, and V_{trigger} represents the trigger voltage.

19. The pulse charging system of claim 15, wherein the cost function is expressed as:
$${min}_{δ SOC , {T}_{rest}} J = {T}_{charge} - β {Q}_{pl}$$
wherein J represents the cost, δSOC represents the change in the state-of-charge of the lithium-ion battery pack, Tᵣₑₛₜ represents the rest time, β represents a weighting factor that is calibrated, Qₚₗ represents the plating intensity, and T_{charge} represents an overall charging time.

20. A pulse charging system for a lithium-ion battery pack for an all-electric vehicle, the pulse charging system comprising:
one or more electric motors that are powered by the lithium-ion battery pack;
one or more controllers in electronic communication with the lithium-ion battery pack and the one or more electric motors, wherein the one or more controllers include one or more processors that execute instructions to:
estimate a plating intensity of the lithium-ion battery pack during two or more initial pulse charging cycles of the lithium-ion battery pack, wherein estimating the plating intensity of the lithium-ion battery pack includes:
determining a state-of-charge of the lithium-ion battery pack; and
controlling power supplied to the lithium-ion battery pack to create the two or more initial pulse charging cycles, wherein the state-of-charge of the lithium-ion battery pack is greater than a pulse state-of-charge of the lithium-ion battery pack at which a current pulse is applied;
estimating a cell impedance of the lithium-ion battery pack for the two or more initial pulse charging cycles based on a change in cell voltage of the lithium-ion battery during a reduced-current mode of a pulse charging cycle and a change in cell current of the lithium-ion battery during a reduced-current mode of the pulse charging cycle;
forming a spline representing a relationship between a trigger voltage and the cell impedance of the lithium-ion battery pack for the two or more initial pulse charging cycles; and
estimating the plating intensity of the lithium-ion battery pack based on a curvature of the spline;
estimate a plurality of pulse charging parameters for the two or more initial pulse charging cycles that include a change in a state-of-charge of the lithium-ion battery and a rest time by minimizing a cost function that produces an output based on the plating intensity;
determine an initial change in the state-of-charge of the lithium-ion battery and an initial rest time during the two or more initial pulse charging cycles by a model-free numerical optimization approach that is based on the cost function;
execute two successive pulse charging cycles that include a first pulse charging cycle and a second pulse charging cycle, wherein the first pulse charging cycle is based on the initial change in the state-of-charge of the lithium-ion battery and the initial rest time, and the second pulse charging cycle is based on a subsequent change in the state-of-charge of the lithium-ion battery and a subsequent rest time;
determine a second updated change in the state-of-charge of the lithium-ion battery and a second updated rest time corresponding to the two successive pulse charging cycles by the model-free numerical optimization approach;
execute a subsequent pulse charging cycle based on the second updated change in the state-of-charge of the lithium-ion battery and the second updated rest time;
calculate an updated plating intensity of the lithium-ion battery pack corresponding to the subsequent pulse charging cycle; and
in response to determining the updated plating intensity falls within an acceptable range of plating intensity values, execute an optimized pulse charging cycle that is based on the updated plating intensity.
